(19) United States
(12) Patent Application Publication
(10) Pub. No.: US 2024/0085882 A1
(43) Pub. Date: Mar. 14, 2024

(54) METHOD OF COMPUTER NUMERICAL CONTROL (CNC) MACHINING AND HYBRID MANUFACTURING

(71) Applicant: University of Tennessee Research Foundation, Knoxville, TN (US)

(72) Inventors: Jake Fielder Dvorak, Knoxville, TN (US); Tony L. Schmitz, Knoxville, TN (US)

(21) Appl. No.: 18/367,112

(22) Filed: Sep. 12, 2023

Related U.S. Application Data
(60) Provisional application No. 63/405,583, filed on Sep. 12, 2022.

(51) Int. Cl. G05B 19/4099; B33Y 80/00; G06F 30/12

(52) U.S. Cl. CPC G05B 19/4099; B33Y 80/00; G06F 30/12

(57) ABSTRACT

A method of computer numerical control (CNC) machining and of hybrid manufacturing are set forth. A more precise alignment of a computer-aided design (CAD) workpiece model, workpiece, and a CNC machine tool is furnished via employment of the method. The method has proved particularly useful for preform workpieces fabricated by additive manufacturing. The part outcome can more closely conform to the intended final part geometry. In an implementation, a coordinate system is established in a CNC machine tool, and a workpiece is fixed in the CNC machine tool. The fixed workpiece is scanned, and the coordinate system is located in the scanned image. Further, a computer-aided design (CAD) model of the workpiece is aligned in the scanned image, and the coordinate system is utilized as the work coordinate system, among other possible steps of the method.

### CROSS-REFERENCE TO RELATED APPLICATION

This application claims the benefit of U.S. Provisional Patent Application No. 63/405,583, with a filing date of Sep. 12, 2022, the contents of which are hereby incorporated by reference in their entirety.

### TECHNICAL FIELD

The present disclosure relates generally to computer numerical control (CNC) machining and generally to hybrid manufacturing and, more particularly, to the alignment of workpieces and models in computer-aided manufacturing (CAM) and CNC machine tools to perform machining operations on the workpieces.

### BACKGROUND

Computer numerical control (CNC) machining involves the automated control of machine tools to carry out machining on workpieces. In a typical operation, programmed machine tool commands are generated by CAM software. Manual operation of the machine tools is frequently unnecessary. Milling and turning machines are among common machine tools equipped with CNC capabilities. Before CNC machining can occur, the position and orientation of workpieces fixed on machine tables should generally be known. Probing the workpieces with touch probes mounted in machine spindles is a common technique used to acquire the position and orientation of the workpieces. But probing can be challenging—and even impractical—for workpieces of irregular shape, and especially for preform workpieces prepared by additive manufacturing which can have non-prismatic shapes and formations.

### SUMMARY

In an embodiment, a method of computer numerical control (CNC) machining may include various steps. One step may involve establishing a coordinate system in a CNC machine tool. Another step may involve fixing a workpiece in the CNC machine tool. A further step may involve scanning the workpiece fixed in the CNC machine tool by way of a three-dimensional (3D) scanner in order to generate a scanned image. The scanned image can contain within its scope the established coordinate system and can contain the workpiece. Yet another step may involve locating the established coordinate system within the scanned image. Another step may involve aligning a computer-aided design (CAD) model of the workpiece within the scanned image. And a further step may involve using the established coordinate system as a work coordinate system of the CNC machine tool.

In another embodiment, a method of hybrid manufacturing may include various steps. One step may involve fabricating a preform workpiece by way of an additive manufacturing process. Another step may involve fixing the preform workpiece in a computer numerical control (CNC) machine tool, as well as fixing one or more fiducials in the CNC machine tool. A further step may involve establishing a coordinate system of the fiducial(s). Yet another step may involve scanning the fiducial(s) and the preform workpiece by way of a three-dimensional (3D) scanner in order to generate a scanned image. Another step may involve locating the established coordinate system of the fiducial(s) within the scanned image. A further step may involve aligning a computer-aided design (CAD) model of the preform workpiece within the scope of the scanned image. Yet another step may involve using the established coordinate system of the fiducial(s) as a work coordinate system of the CNC machine tool. And another step may involve determining computer-aided manufacturing (CAM) toolpath commands of the CNC machine tool for machining the preform workpiece based on the established coordinate system of the fiducial(s).

In yet another embodiment, a method of hybrid manufacturing may include various steps. One step may involve fabricating a preform workpiece by way of an additive manufacturing process. Another step may involve fixing the preform workpiece in a computer numerical control (CNC) machine tool, as well as fixing one or more fiducials in the CNC machine tool. Another step may involve aligning the fiducial(s) with axes of the CNC machine tool. A further step may involve establishing a coordinate system of the fiducial(s). Yet another step may involve scanning the fiducial(s) and the preform workpiece by way of a three-dimensional (3D) scanner in order to generate a scanned image. Another step may involve locating the established coordinate system of the fiducial(s) within the scope of the scanned image. A further step may involve aligning a computer-aided design (CAD) model of the preform workpiece within the scanned image. Yet another step may involve using the established coordinate system of the fiducial(s) as a work coordinate system of the CNC machine tool. And another step may involve machining the preform workpiece by way of the CNC machine tool based on the established coordinate system of the fiducial(s).

### BRIEF DESCRIPTION OF THE DRAWINGS

One or more aspects of the disclosure will hereinafter be described in conjunction with the appended drawings, wherein like designations denote like elements, and wherein:

FIG. 1A depicts an embodiment of computer-aided design (CAD) model of a workpiece;

FIG. 1B depicts an embodiment of a preform workpiece fabricated by an additive manufacturing process;

FIG. 1C depicts the preform workpiece located on a machine table of a CNC machine tool;

FIG. 1D depicts the preform workpiece fixed in place in the CNC machine tool, and demonstrates a skew and misalignment between axes of the preform workpiece and the CNC machine tool;

FIG. 1E depicts a simulated preform workpiece outcome;

FIG. 2 is an image of an embodiment of a workpiece and an example fiducial located on a machine table of a CNC machine tool;

FIG. 3 is a flow chart of an embodiment of a method of computer numerical control (CNC) machining and hybrid manufacturing, the flow chart presenting some steps of the method;

FIG. 4 is a flow chart of an embodiment of a method of computer numerical control (CNC) machining and hybrid manufacturing, the flow chart presenting some steps of the method;

FIG. 5A shows a scanned image of the fiducial with a first fitted plane;

FIG. 5B shows a scanned image of the first fitted plane;

FIG. 5C shows a scanned image of the fiducial with the first fitted plane removed;

FIG. 5D shows a scanned image of a second fitted plane;

FIG. 5E shows a subsequent scanned image of the fiducial;

FIG. 6A shows an image of planes aligned with the fiducial;

FIG. 6B shows a subsequent image of planes aligned with the fiducial;

FIG. 6C shows a subsequent image of planes aligned with the fiducial;

FIG. 6D shows a subsequent image of planes aligned with the fiducial;

FIG. 6E shows a subsequent image of planes aligned with the fiducial;

FIG. 6F shows a subsequent image of planes aligned with the fiducial;

FIG. 6G shows a subsequent image of planes aligned with the fiducial; and

FIG. 6H shows a subsequent image of planes aligned with the fiducial.

### DETAILED DESCRIPTION

Referring generally to the drawings, embodiments of a method of computer numerical control (CNC) machining and, more generally, of hybrid manufacturing are depicted and described herein. As set forth, the method furnishes a more precise alignment of a computer-aided design (CAD) workpiece model, a workpiece itself, and a CNC machine tool than previously demonstrated. Enhanced accuracy of intended final part geometry is hence enabled and attainable. The method, per an embodiment, may involve the use of handheld scanners such as mobile phones, which typically have a lower cost compared to larger and more stationary scanners, although stationary scanners are possible in certain embodiments. Handheld scanning can provide greater mobility in a scanning procedure of the method, facilitating scanning of workpieces of any shape and while the workpieces are fixed in place in CNC machine tools. Furthermore, and unlike past approaches, unconventional fixing and clamping of workpieces for CNC machining—previously inconvenient or even impractical due to challenges encountered with workpieces of irregular shape—can be employed in the method. The method has proved particularly useful with preform workpieces fabricated by additive manufacturing. Preform workpieces can be somewhat rough in nature in terms of their formation, and can exhibit non-prismatic shapes; still, the method may be useful with other types of workpieces prepared in other ways. Also, preform workpieces often have formations that are unexpected and that do not correspond to the geometry intended via additive manufacturing. The method accounts for such non-correspondence. Lastly, the method can be integrated with computer-aided manufacturing (CAM) software of typical CNC machine tools, and does not call for new CAM software for its implementation.

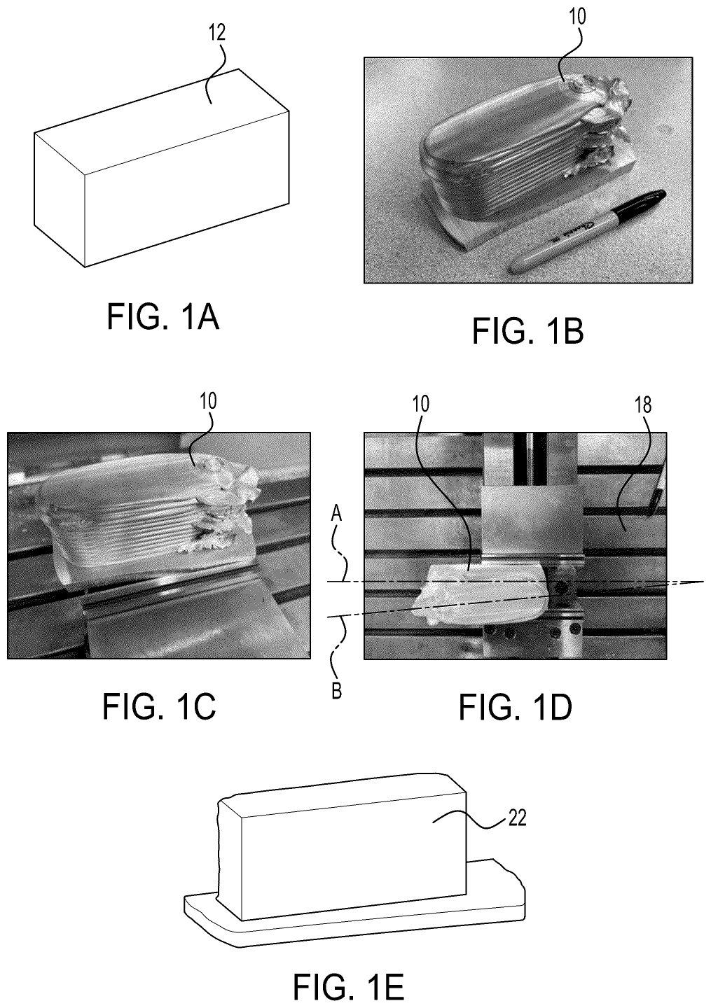

The method of CNC machining and hybrid manufacturing may have varied steps according to different embodiments, and may have more, less, and/or different steps than those presented herein. Indeed, the steps of the method may at least partly be dictated by the formation and shape of the workpiece and the fidelity of scanned images. The steps need not necessarily be performed in the particular order described and depicted. With general reference to FIGS. 1A-1E, in this embodiment the method involves fabricating a preform workpiece 10 via an additive manufacturing process. The preform workpiece 10 is shown in FIGS. 1B, 1C, and 1D in an as-printed state from a three-dimensional (3D) printing additive manufacturing process, and includes a build plate. The preform workpiece can be composed of a metal material or a plastic material, as examples.

The method is a hybrid manufacturing process that combines additive manufacturing and CNC machining. The additive manufacturing process is carried out initially to prepare the preform workpiece 10, and the CNC machining process is subsequently carried out to bring the preform workpiece 10 to its intended final part geometry. Examples of additive manufacturing processes include 3D printing and friction stir additive manufacturing (FSAM); still, other types and techniques of additive manufacturing processes are possible. Examples of common CNC machine tools include CNC milling machine tools and CNC turning machine tools; still, other types of CNC machine tools are possible. A computer-aided design (CAD) model 12 (FIG. 1A) and representation is used in the additive manufacturing process amid directives and commands for depositing material layer-upon-layer to produce the preform workpiece 10. Oftentimes, the preform workpiece 10 lacks precision relative to the CAD model 12 and relative to the intended final part geometry, as is evident from a comparison of FIGS. 1A and 1B. The CNC machining process is performed to enhance precision in this regard.

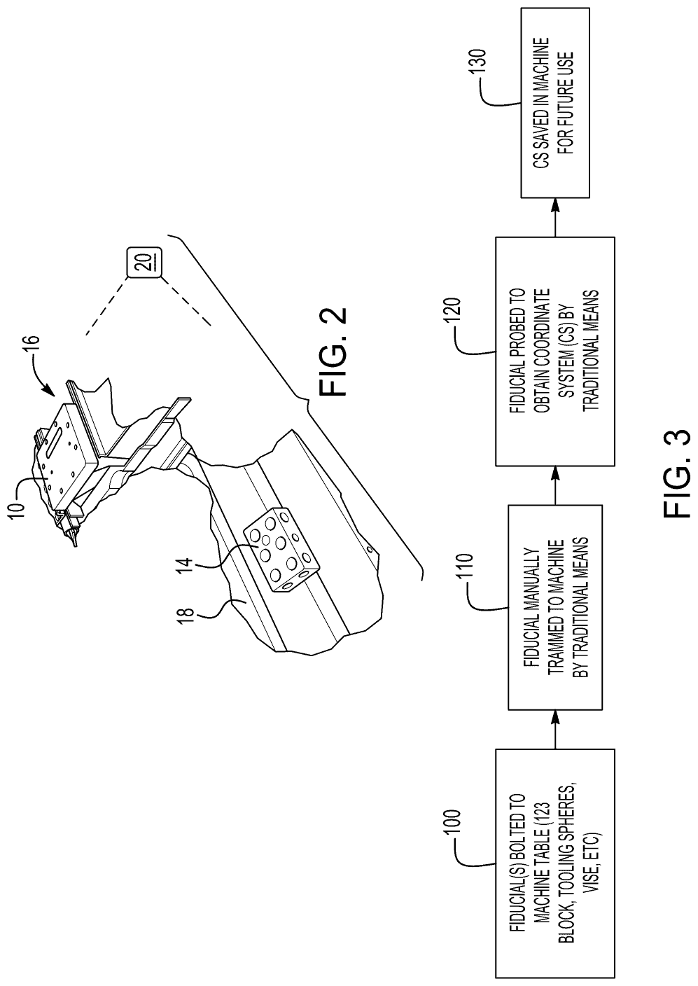

Referring now to FIGS. 2 and 3, in this embodiment a step 100 of the method involves fixing one or more fiducials 14 in a CNC machine tool 16. The fiducial(s) 14 serves to facilitate workpiece location in the method. The fiducial(s) 14 can take various forms including three planes of a 123 block (shown in the example of FIG. 2), centers of two tooling spheres, three faces of a vise, or some other object. The fiducial(s) 14 can be fixed to a machine table 18 of the CNC machine tool 16 in various ways, including via bolting, clamping, or some other technique. The fiducial(s) 14 can be unattached and spaced from, and somewhat remote of, the preform workpiece 10 on the machine table 18, as an example. Once fixed, the method may further involve a step 110 of aligning the fiducial(s) 14 with axes of the CNC machine tool 16 at the machine table 18. The fiducial(s) 14 can be manually trammed with the axes by various ways including with the use of a dial indicator or by some other technique. After tramming, the fiducial(s) 14 remains aligned with the axes. Like some other steps described elsewhere, the step 110 need not necessarily be carried out in the method. Furthermore, a step 120 of the method involves establishing a coordinate system of the fiducial(s) 14 while the fiducial(s) 14 is fixed to the machine table 18 of the CNC machine tool 16. The coordinate system can be established by various ways including via probing with a touch probe assembled in a machine spindle of the CNC machine tool 16. Lastly, in FIG. 3, the method involves a step 130 of saving the established coordinate system of the fiducial(s) 14 in the CNC machine tool 16 such as within a controller of the CNC machine tool 16. The fiducial(s) 14 may remain fixed to the machine table 18 after its coordinate system is established. The established coordinate system is unaltered between succeeding and differing CNC machining jobs on discrete workpieces. As described, the steps 100, 110, 120, and 130 in FIG. 3 take place before the scanning procedure is carried out. Still, in an alternative embodiment of the method, one or more discrete fiducial components need not be used. Instead, a coordinate system could be established based on the CNC machine tool 16 itself. In an example, the machine table 18 could be subject to the establishment of a coordinate system, or some other component of the CNC machine tool 16. In effect, in this alternative embodiment, the CNC machine tool 16 and one or more of its components serves as the fiducial.

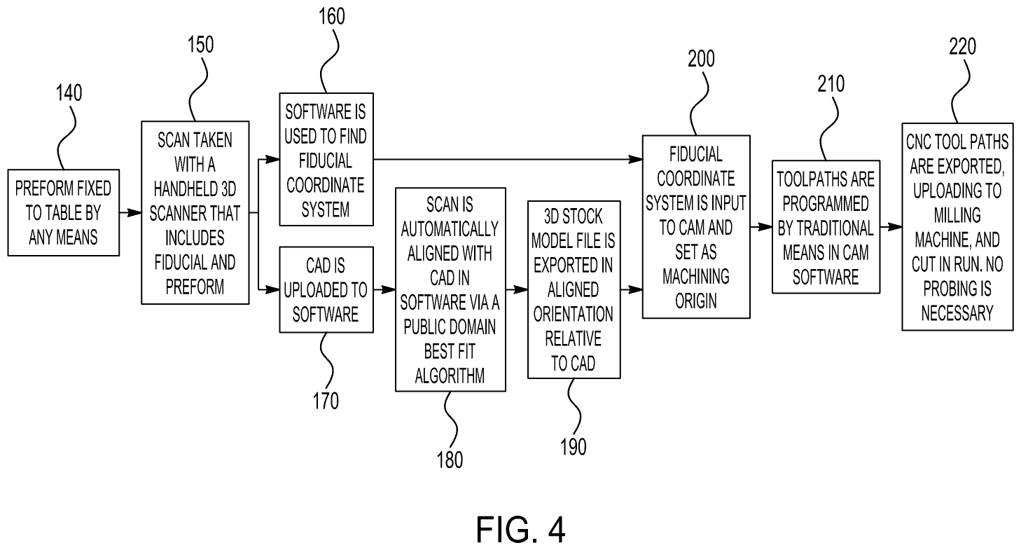

The scanning procedure, as well as other steps, is presented in FIG. 4. In this embodiment, a step 140 of the method involves fixing the preform workpiece 10 in the CNC machine tool 16 and to the machine table 18. The preform workpiece 10 can be fixed to the machine table 18 of the CNC machine tool 16 in various ways, including those previously considered inconvenient and impractical due to challenges encountered with locating workpieces of irregular and non-prismatic shape such as some preform workpieces, but also other types of workpieces. The scanning procedure resolves these challenges, permitting unconventional fixing and clamping techniques of the preform workpiece 10 to the machine table 18 including via a fractal vise, a vise with pins, clamping directly to the machine table 18, as well as other unusual clamping styles and techniques. Past requirements of tramming the clamping systems in alignment with machine axes, or manually rotating and translating the workpieces in alignment with machine axes, are accounted for by the scanning procedure and hence unneeded with use of the method.

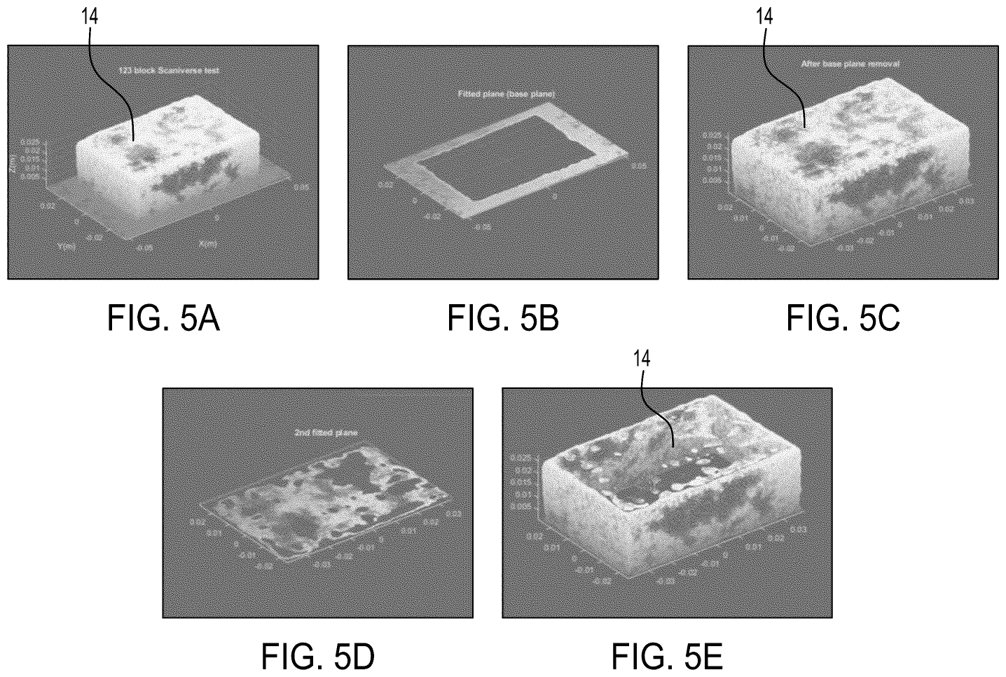

Once fixed, the method further involves a step 150 of scanning the fiducial(s) 14 and the preform workpiece 10 as they are fixed in place on the machine table 18 and in the CNC machine tool 16. The position and orientation of the preform workpiece 10 relative to the machine table 18 and with respect to the fiducial(s) 14 can be unknown at this point, as it is accounted for by the scanning procedure; the fiducial(s) 14, in contrast, has a known position and orientation at the point of scanning as a result of its already-established coordinate system. FIG. 1D presents an example in which an axis A of the preform workpiece 10 and an axis B of the CNC machine tool 16 are misaligned and askew, and yet accounted for by the scanning procedure. The scanning generates a scanned image that contains the fiducial(s) 14 and the preform workpiece 10 within its scope. FIGS. 5A-5E shows example scanned images of the fiducial(s) 14 and varying subsequent imagery thereof including with and without fitted planes.

According to this embodiment, a three-dimensional (3D) handheld scanner 20 (FIG. 2) is used to generate the scanned image. The 3D handheld scanner 20 can take different forms in different embodiments. In one example, the 3D handheld scanner 20 is a mobile phone such as an Apple iPhone® 12 or an Apple iPhone® 13; still, other kinds of mobile phones made by other providers are possible. Mobile phones can be equipped with LiDAR scanners and multiple cameras that generate scanned images—it has been found that the fidelity of such scanned images is suitable for use in the method. A mobile application such as Scaniverse provided by Toolbox AI, Inc. can be run as part of the scanning step. The Scaniverse application employs LiDAR and photogrammetry; still, other applications and/or software may be suitable. The images of FIGS. 5A-5E were generated by way of the Scaniverse application. Handheld scanning provides increased mobility in the scanning procedure by virtue of a decreased form factor, facilitating scanning of the fiducial(s) 14 and the preform workpiece 10 while they are fixed on the machine table 18. Scanning of workpieces of irregular and non-prismatic shapes is also facilitated with the use of handheld scanning. Moreover, and more generally, 3D handheld scanners typically have a lower cost compared to larger and more stationary scanners. In other embodiments, the 3D handheld scanner 20 could be in the form of other types of mobile devices such as tablets or watches or some other device. Still, in yet other embodiments, scanners mounted on or adjacent the CNC machine tool 16 could be employed in the method; such scanners need not necessarily be handheld and/or mobile.

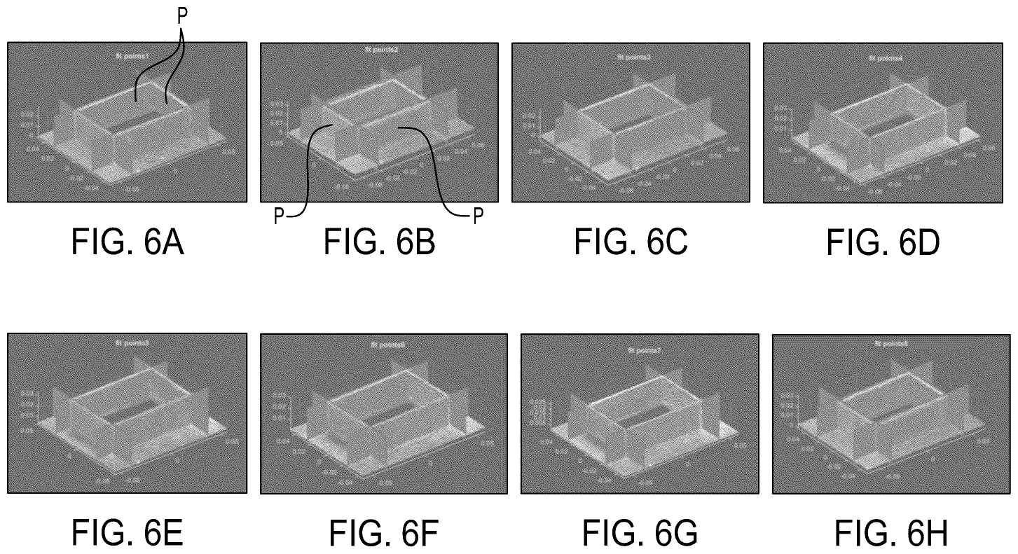

With continued reference to FIG. 4, in this embodiment a step 160 of the method involves locating the previously-established coordinate system of the fiducial(s) 14 within the generated scanned image. A software such as MATLAB or GOM Inspect can be employed for this purpose. The software can be run on a computer external of the CNC machine tool 16, for example. The fiducial coordinate system can be automatically found via the software. FIGS. 6A-6H present an example of locating the coordinate system of the fiducial(s) 14 in the scanned image by aligning planes P to the scanned image of the fiducial(s) 14. Further, the method involves a step 170 of uploading the CAD model 12 of the preform workpiece 10 to the software. A step 180 of the method involves aligning the CAD model 12 of the preform workpiece 10 within the generated scanned image. A best-fit algorithm and software can be executed for this purpose, per an embodiment. Certain open-source libraries can be accessed for a best-fit algorithm, including those found at web addresses: https://github com/nmoehrle/mvs-texturing, https://colmap.github.io/, https://github.com/mkazhdan/PoissonRecon, and https://www.vlfeat.org/, as but a few examples. Still, other ways of realizing alignment of the CAD model 12 and scanned images are possible.

Furthermore, the method involves a step 190 of exporting a three-dimensional (3D) stock model file of the scanned image with the CAD model 12 aligned. The 3D stock model file is exported from the best-fit software, according to this embodiment. A step 200 of the method involves using the established coordinate system of the fiducial(s) 14 as a work coordinate system (WCS) and as a machining origin of the CNC machine tool 16. The fiducial coordinate system is inputted to the CAM software of the CNC machine tool 16 in this step, and set as the WCS and machining origin of the CNC machine tool 16. Then, in a step 210, toolpath commands and machining parameters of the CNC machine tool 16 are programmed by traditional means in the CAM software. The toolpath commands are determined based on the fiducial coordinate system being set as the WCS and machining origin of the CNC machine tool 16. Lastly, in FIG. 4, the method involves a step 220 of exporting the determined toolpath commands to the CNC machine tool 16, where they are uploaded for use. Machining such as cutting is then carried out by the CNC machine tool 16. FIG. 1E presents a simulated preform workpiece 22 outcome that conforms more closely to the intended final part geometry than previously demonstrated. In the method steps of FIG. 4, probing need not necessarily be performed on the preform workpiece 10 in order to complete the method of CNC machining and hybrid manufacturing. Furthermore, in another embodiment of the method, multiple workpieces could be fixed in the CNC machine tool 16 with a single fiducial 14, and then all scanned together in the same scanned image; here, individual workpieces could be processed separately, and then toolpath commands could be programmed in the CAM software for all of the workpieces.

Overall, the method set forth herein provides more precise alignment among the preform workpiece 10, CAD model 12, and the work coordinate system than previously demonstrated. After CNC machining, the part outcome more closely conforms to the intended final part geometry. That is, the scanned image of the preform workpiece 10 exhibits increased accuracy of the physical geometry of the preform workpiece 10. The scanned image of the preform workpiece 10 is more precisely aligned with the CAD model 12 and in a common coordinate system. Accordingly, observations can be made in the CAM software to identify any potential gaps or other unwanted issues that could propagate to the part outcome amid CNC machining. Adjustments to the CAM software can be made, in advance, in order to minimize or altogether avoid such gaps and unwanted issues. The work coordinate system of the CNC machine tool 16 is effectively transferred wholly to the CAD model 12 itself.

At least some of the steps of the method of CNC machining and of the method of hybrid manufacturing can be carried out and executed as a mobile application and/or computer program and/or software application run on a mobile device, according to some embodiments. For example, the step 180 of aligning the CAD model 12 of the preform workpiece 10 within the generated scanned image could be performed in a mobile application and/or computer program and/or software application run on a mobile device.

As used herein, the terms “general” and “generally” are intended to account for the inherent degree of variance and imprecision that is often attributed to, and often accompanies, any design and manufacturing process, including engineering tolerances— and without deviation from the relevant functionality and outcome—such that mathematical precision and exactitude is not implied and, in some instances, is not possible. In other instances, the terms “general” and “generally” are intended to represent the inherent degree of uncertainty that is often attributed to any quantitative comparison, value, and measurement calculation, or other representation.

It is to be understood that the foregoing is a description of one or more aspects of the disclosure. The disclosure is not limited to the particular embodiment(s) disclosed herein, but rather is defined solely by the claims below. Furthermore, the statements contained in the foregoing description relate to particular embodiments and are not to be construed as limitations on the scope of the disclosure or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “e.g.,” “for example,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

What is claimed is:

1. A method of computer numerical control (CNC) machining, the method comprising:
establishing a coordinate system in a CNC machine tool;
fixing a workpiece in the CNC machine tool;
scanning the workpiece fixed in the CNC machine tool via a three-dimensional (3D) scanner to generate a scanned image, the scanned image containing the established coordinate system and the workpiece;
locating the established coordinate system within the scanned image;
aligning a computer-aided design (CAD) model of the workpiece within the scanned image; and
using the established coordinate system as a work coordinate system of the CNC machine tool.

2. The method as set forth in claim 1, wherein:
the established coordinate system is a coordinate system of at least one fiducial fixed in the CNC machine tool;
scanning the workpiece comprises scanning the at least one fiducial fixed in the CNC machine tool, the scanned image containing the at least one fiducial and the workpiece;
locating the established coordinate system comprises locating the coordinate system of the at least one fiducial within the scanned image; and
using the established coordinate system comprises using the established coordinate system of the at least one fiducial as the work coordinate system of the CNC machine tool.

3. The method as set forth in claim 2, further comprising, before establishing the coordinate system of the at least one fiducial fixed in the CNC machine tool, aligning the at least one fiducial with axes of the CNC machine tool.

4. The method as set forth in claim 1, further comprising fabricating the workpiece via an additive manufacturing process.

5. The method as set forth in claim 2, wherein the established coordinate system of the at least one fiducial is established via probing.

6. The method as set forth in claim 1, wherein the 3D scanner is a 3D handheld scanner.

7. The method as set forth in claim 6, wherein the 3D handheld scanner is a mobile device.

8. The method as set forth in claim 7, wherein the mobile device is a mobile phone with a LiDAR scanner and photogrammetry.

9. The method as set forth in claim 2, further comprising, after an initial scanning of the at least one fiducial and the workpiece fixed in the CNC machine tool via the 3D scanner to generate the scanned image, performing subsequent scans of workpieces fixed in the CNC machine tool via the 3D scanner to generate subsequent scanned images with the at least one fiducial remaining fixed in the CNC machine tool.

10. The method as set forth in claim 1, further comprising determining computer-aided manufacturing (CAM) toolpath commands of the CNC machine tool for machining the workpiece based on the established coordinate system.

11. The method as set forth in claim 1, wherein the method of computer numerical control (CNC) machining is carried out in the absence of probing the workpiece while the workpiece is fixed in the CNC machine tool.

12. The method as set forth in claim 1, wherein:
fixing the workpiece in the CNC machine tool comprises fixing a plurality of workpieces in the CNC machine tool;
scanning the workpiece comprises scanning the plurality of workpieces fixed in the CNC machine tool; and
aligning the CAD model of the workpiece comprises aligning a plurality of CAD models of the plurality of workpieces within the scanned image.

13. A method of hybrid manufacturing, the method comprising:
fabricating a preform workpiece via an additive manufacturing process;
fixing the preform workpiece in a computer numerical control (CNC) machine tool, and fixing at least one fiducial in the CNC machine tool;
establishing a coordinate system of the at least one fiducial;
scanning the at least one fiducial and the preform workpiece via a three-dimensional (3D) scanner to generate a scanned image;
locating the established coordinate system of the at least one fiducial within the scanned image;
aligning a computer-aided design (CAD) model of the preform workpiece within the scanned image;
using the established coordinate system of the at least one fiducial as a work coordinate system of the CNC machine tool; and
determining computer-aided manufacturing (CAM) toolpath commands of the CNC machine tool for machining the preform workpiece based on the established coordinate system of the at least one fiducial.

14. The method as set forth in claim 13, wherein the method of hybrid manufacturing is carried out in the absence of probing the workpiece while the workpiece is fixed in the CNC machine tool.

15. The method as set forth in claim 13, further comprising, before establishing the coordinate system of the at least one fiducial, aligning the at least one fiducial with axes of the CNC machine tool.

16. The method as set forth in claim 13, wherein the established coordinate system of the at least one fiducial is established via probing.

17. The method as set forth in claim 13, wherein the 3D scanner is a 3D handheld scanner.

18. The method as set forth in claim 13, wherein:
fixing the preform workpiece in the CNC machine tool comprises fixing a plurality of preform workpieces in the CNC machine tool;
scanning the at least one fiducial and the preform workpiece comprises scanning the at least one fiducial and the plurality of preform workpieces; and
aligning the CAD model of the preform workpiece comprises aligning a plurality of CAD models of the plurality of preform workpieces within the scanned image.

19. A method of hybrid manufacturing, the method comprising:
fabricating a preform workpiece via an additive manufacturing process;
fixing the preform workpiece in a computer numerical control (CNC) machine tool, and fixing at least one fiducial in the CNC machine tool;
aligning the at least one fiducial with axes of the CNC machine tool;
establishing a coordinate system of the at least one fiducial;
scanning the at least one fiducial and the preform workpiece via a three-dimensional (3D) scanner to generate a scanned image;
locating the established coordinate system of the at least one fiducial within the scanned image;
aligning a computer-aided design (CAD) model of the preform workpiece within the scanned image;
using the established coordinate system of the at least one fiducial as a work coordinate system of the CNC machine tool; and
machining the preform workpiece via the CNC machine tool based on the established coordinate system of the at least one fiducial.

20. The method as set forth in claim 19, wherein:
the 3D scanner is a 3D handheld scanner;
fixing the preform workpiece in the CNC machine tool comprises fixing a plurality of preform workpieces in the CNC machine tool;
scanning the at least one fiducial and the preform workpiece comprises scanning the at least one fiducial and the plurality of preform workpieces; and
aligning the CAD model of the preform workpiece comprises aligning a plurality of CAD models of the plurality of preform workpieces within the scanned image.
